(19) United States
(12) Patent Application Publication
(10) Pub. No.: US 2009/0256229 A1
(43) Pub. Date: Oct. 15, 2009

(54) Semiconductor Package, Method for Manufacturing the Same, Semiconductor Module, and Electronic Device

(75) Inventors: Kazuhiro Ishikawa, Kanagawa (JP); Katsuitsu Nishida, Kyoto (JP); Kazuya Fujita, Mie (JP); Takahiro Nakahashi, Nara (JP)

Correspondence Address: EDWARDS ANGELL PALMER & DODGE LLP, P.O. BOX 55874, BOSTON, MA, 02205, US

(73) Assignee: SHARP KABUSHIKI KAISHA, Osaka-shi (JP)

(21) Appl. No.: 12/085,152

(22) PCT Filed: Nov. 1, 2006
(86) PCT No.: PCT/JP2006/321898

§ 371 Date: May 15, 2008

(30) Foreign Application Priority Data
Nov. 16, 2005 (JP) 2005-331812

(51) Int. Cl. H01L 31/04; H01L 23/02; H01L 21/00

(52) U.S. Cl. 257/434; 257/680; 438/113; 257/E21.002; 438/116; 438/118

(57) ABSTRACT

In a camera module (1) of the present invention, a lens member (20) is attached to a semiconductor package (10). The semiconductor package (10) includes: an image sensor (11) mounted on a wiring board (13); and a wire 15 through which the wiring board (13) is electrically connected to the image sensor (11). The image sensor (11) and the wire 15 are sealed with mold resin (14). A step (18) is formed around the perimeter of the surface of the mold resin (14), and the semiconductor package (10) and the lens member (20) are joined by fitting the step (18) and a projection (23) of a lens holder (22). With this arrangement, it is possible to realize a small semiconductor module that allows for highly precise alignment between the semiconductor package and a mounting component to which the semiconductor package is joined.

### TECHNICAL FIELD

The present invention relates to a semiconductor package, a method for manufacturing the same, a semiconductor module including the semiconductor package, and an electronic device including the semiconductor module.

### BACKGROUND ART

In recent years, electronic cameras including an image pickup element have been used for various electronic devices such as mobile phones, personal digital assistants, personal computers and digital still cameras. At present there have been demands for downsizing and cost reduction on these electronic cameras. Therefore there has been increasing use of a downsized camera module into which an image sensor (semiconductor chip) and a lens are integrated (packaged).

Thus, demands for downsizing of a camera module have been increasing. However, the size of the area which is used for alignment with an image sensor and a lens holder supporting a lens has a great influence on a module size these days.

For example, downsized camera modules are disclosed in Patent documents 1 through 4. FIG. 6 through FIG. 9 are cross-sectional views showing the structures of camera modules disclosed in Patent documents 1 through 4.

As FIG. 6 shows, a camera module 100 of Patent document 1 includes a semiconductor chip 111 which mounted on a board 113. The semiconductor chip 111 contains an image sensor, a signal processing circuit, and other parts. The semiconductor chip 111 is surrounded by a hollow cover frame member 114 and an optical member 112 for shielding infrared light. The optical member 112 is attached so as to block the opening of the cover frame member 114. The cover frame member 114 and the optical member 112 for shielding infrared light are hermetically sealed in a lens holder 122. The lens holder 122 is bonded on the board 113 in the area other than the area where the semiconductor chip 111 is mounted and outside the cover frame member 114. Thus, the camera module 100 is arranged so that the semiconductor chip 111, the cover frame member 114 and the lens holder 122 are bonded on the same reference surface of the board 113.

As FIG. 7(a) and FIG. 7(b) show, a camera module 200 disclosed in Patent document 2 is arranged such that a semiconductor chip (image sensor) 211 on a board 213 is hermetically sealed in a housing 214. The housing 214 has steps 218 with round sides formed by circular processing. By press-fitting the lens holder 222 into the step 218 of the housing 214, the housing 214 and the lens holder 222 are fixed without special fixing means and play.

As FIG. 8 shows, a camera module 300 disclosed in Patent document 3 is arranged such that a lens holder (resin lens barrel) 322 having a lens fit therein is attached to a resin forming member 314 which seals a semiconductor chip 311 on a board 313.

As FIG. 9 shows, a camera module 400 disclosed in Patent document 4 is arranged such that a lens holder 422 is mounted on a semiconductor package 410 having a sealing member 414. In the sealing member 414, (i) a semiconductor chip 411 which is mounted on a board 413 and (ii) a wire 415 through which the semiconductor chip 411 and the board 413 are connected to each other are sealed with resin.

### [Patent Document 1]

Japanese Unexamined Patent Application Publication No. 2000-125212 (published on Apr. 28, 2000)

### [Patent Document 2]

Japanese Unexamined Patent Application Publication No. 2003-110946 (published on Apr. 11, 2003)

### [Patent Document 3]

Japanese Unexamined Patent Application Publication No. 2005-184630 (published on Jul. 7, 2005)

### [Patent Document 4]

Japanese Unexamined Patent Application Publication No. 2004-296453 (published on Oct. 21, 2004)

### DISCLOSURE OF INVENTION

Not only downsizing but also alignment between a semiconductor chip and a lens member are important in the camera modules as above. Misalignment therebetween worsens the function of a camera. Therefore it is necessary for them to be aligned with high precision.

However, the conventional arrangements cannot fully meet the needs for downsizing of a camera module and highly precise alignment between the semiconductor chip and the lens member.

According to the arrangements of Patent documents 1 through 3, the semiconductor chips (semiconductor chip 111, 211, 311) and the wires 215 and 315 are not sealed with resin. Therefore the total size of the camera module (board size) is far larger than the size of the semiconductor chip.

According to the arrangement of Patent document 1, as FIG. 6 shows, the whole cover frame member 114 which seals the semiconductor chip 111 is covered with the lens holder 122. More specifically, according to the arrangement of Patent document 1, the position (bonding position) of the lens holder 122 on the surface of the board 113 is fixed by the hollow cover frame member 114 with which the semiconductor chip 111 is covered. The board 113 requires the mounting area of the semiconductor chip 111 and the bonding area of the hollow cover frame member 114 and the lens holder 122. This makes the size of the board 113 larger than that of the semiconductor chip 111.

Similarly, according to the arrangement disclosed in Patent document 2 as shown in FIG. 7(a) and FIG. 7(b), the whole housing 214 which seals the semiconductor chip 211 is covered with the lens holder 222. This makes the board size even larger than the size of the semiconductor chip.

Also as FIG. 7(a) and FIG. 7(b) show, the lens holder 222 to be press-fit sticks out of the step 218 which is formed in the housing 214 sealing the semiconductor chip 211. Moreover according to the arrangement of Patent document 2, the step 218 and the lens holder 222 are joined to each other by press-fitting. However, since an adhesive isn't used in press-fitting, the step 218 must be formed very accurately to align the semiconductor chip 211 with the housing 214 with high precision.

According to the arrangement disclosed in Patent document 2, because the shape of the step 218 is substantially circular, step-forming must be performed using a special housing mold. According to the arrangement disclosed in Patent document 3, the resin-forming member 314 is formed by transfer molding, injection molding, or the like. However, the method of forming the step using a special mold requires special molds for each of the steps of different shapes and sizes. This causes the increase in parts count and extremely low versatility of step formation, and requires a significant capital investment for each type of steps. And if the special molds are used, the number of the parts increases accordingly.

According to the arrangement of Patent document 4, the semiconductor package 410 and the lens holder 422 are aligned with each other by surface contact between the bottom surface of the lens holder 422 and the surface of the sealing member 414. In this case they can be aligned in the optical axis direction (lengthwise or vertically), but they can be misaligned horizontally (crosswise). This may cause displacement of the optical axis from the right position.

Thus, the conventional semiconductor module in which a mounting component is attached to the semiconductor package cannot fully meet the needs for downsizing of the semiconductor module and alignment between the semiconductor package and the mounting component.

The present invention has been attained in view of the above problems, and an object of the present invention is to realize a semiconductor module that allows for its downsizing and highly precise alignment between a semiconductor package constituting the semiconductor module and the mounting component. Another object of the present invention is to provide a method for manufacturing a semiconductor package used suitably in such a semiconductor module and the use of the semiconductor module.

In order to solve the above problems, a semiconductor package according to the present invention is a semiconductor package including: a semiconductor chip mounted on a wiring board; a connecting member through which the wiring board is electrically connected to the semiconductor chip; and a resin sealing member for sealing the semiconductor chip and the connecting member with resin, wherein a step is formed around a perimeter of a surface of the resin sealing member.

According to the above arrangement, the components sealed with resin include the connecting member through which the board is electrically connected to the optical element. In other words, the semiconductor package according to the present invention is the so-called chip-size package. Therefore it is possible to realize the super-small semiconductor package of the same size as the optical element.

Furthermore, according to the above arrangement, the step is formed around the perimeter of the resin sealing member. By attaching the mounting component which fits in this step to the semiconductor package, it is possible to form a semiconductor module that allows for highly precise alignment lengthwise and crosswise. That is, the semiconductor package of the present invention can be applied suitably to such a semiconductor module.

Thus, a semiconductor package according to the present invention is arranged such that the step is formed around the perimeter of the surface of the resin sealing member. This makes it possible to realize a super-small semiconductor package and a semiconductor package which is suitable for the semiconductor module which allows for highly precise alignment lengthwise and crosswise by attaching the mounting component which fits in this step to the semiconductor package.

In order to solve the above problem, a method for manufacturing a semiconductor package according to the present invention is a method for manufacturing a semiconductor package including: a semiconductor chip mounted on a wiring board; a connecting member through which the wiring board is electrically connected to the semiconductor chip; and a resin sealing member for sealing the semiconductor chip and the connecting member with resin, the method including: the step forming step of forming a step around a perimeter of a surface of the resin sealing member.

According to the above method, the step forming step is included. This makes it possible to manufacture a semiconductor package that is suitable for the semiconductor module as described previously, i.e. the semiconductor module that allows for highly precise alignment lengthwise and crosswise.

Additional objects, features, and strengths of the present invention will be made clear by the description below. Further, the advantages of the present invention will be evident from the following explanation in reference to the drawings.

### BRIEF DESCRIPTION OF DRAWINGS

FIG. 1 is a cross-sectional view of a camera module according to the present invention.

FIG. 2 is a cross-sectional view of a semiconductor package in the camera module shown in FIG. 1.

FIG. 3 is a top view of the semiconductor package shown in FIG. 2.

FIG. 4 is a view showing the manufacturing process of semiconductor package shown in FIG. 2.

FIG. 5(a) is a process diagram showing a step for the manufacture the camera module according to the present invention.

FIG. 5(b) is a process diagram showing a step following the step shown in FIG. 5(a) for the manufacture of the camera module according to the present invention.

FIG. 5(c) is a process diagram showing a step following the step shown in FIG. 5(b) for the manufacture of the camera module according to the present invention.

FIG. 6 is a cross-sectional view of a camera module described in Patent document 1.

FIG. 7(a) is a perspective view of a camera module described in Patent document 2.

FIG. 7(b) is a cross-sectional view taken along A-A line of the camera module shown in FIG. 7(a).

FIG. 8 is a cross-sectional view of a camera module described in Patent document 3.

FIG. 9 is a cross-sectional view of a camera module described in Patent document 4.

### BEST MODE FOR CARRYING OUT THE INVENTION

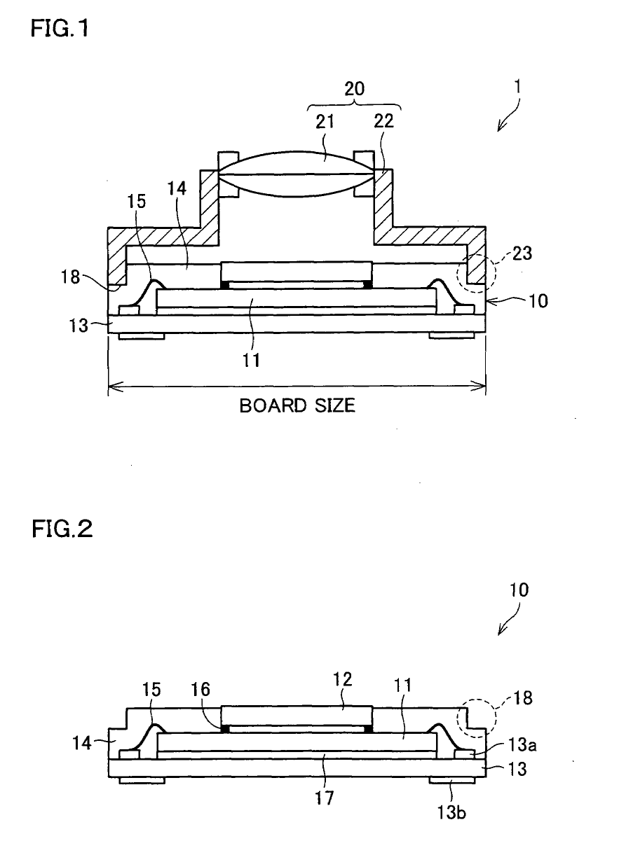

One embodiment of the present invention is described below with reference to FIG. 1 through FIG. 5.

(1) Camera Module in Accordance with the Present Invention

FIG. 1 shows a cross-sectional view of a camera module 1 in accordance with the present embodiment. The camera module 1 has the structure in which a lens member 20 is integrally attached to a semiconductor package 10.

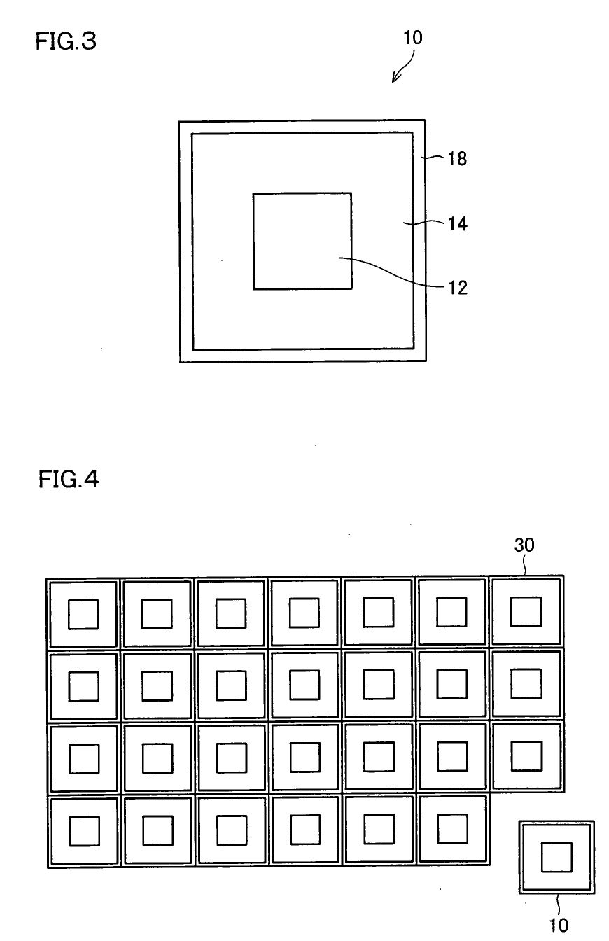

FIG. 2 is a cross-sectional view of the semiconductor package 10 and FIG. 3 is a top view of the semiconductor package 10. The semiconductor package 10 has the structure in which an image sensor 11 is mounted on a print wiring board 13 (hereinafter referred to as “the wiring board”) 13.

The wiring board 13 has wiring pattern formed thereon. The wiring board 13 has a wire bond terminal 13a provided on its surface where the image sensor 11 is mounted, and has an external connection electrode 13b provided on the other side (backside). The wire bond terminal 13a and the external connection electrode 13b are electrically connected with each other.

The image sensor 11 is a solid image sensing element consisting of a semiconductor chip and has a lid (not shown). The image sensor 11 is fixed on the wiring board 13 with a die bond material 17. A pad (not shown) of the image sensor 11 and the wire bond terminal 13a of the wiring board 13 are electrically connected with each other via the wire (connecting member) 15. The die bond material 17 may be in the form of a paste or a sheet.

The image sensor 11 has a pixel area formed on its surface. This pixel area is an area (light transmitting area) which allows light entering from the lens member 20 to pass through. On the pixel area (light transmitting area) of the image sensor 11, a glass 12 is mounted through a resin 16 which is provided around the pixel area. In other words, the pixel area of the image sensor 11 is covered with the glass 12 (transparent cover) with space therebetween.

The above-mentioned components on the wiring board 13 are sealed with a mold resin (a resin forming member; a resin) 14 in the semiconductor package 10. In other words, the semiconductor package 10 has the so-called CSP (Chip Scale Package) structure. In other words, in the semiconductor package 10, not only the image sensor 11 but also the wire 15 through which the image sensor 11 is electrically connected with the wiring board 13 are sealed with the mold resin 14. Therefore the semiconductor package 10 has the structure suitable for a super-small and super-slim module. The semiconductor package 10 may be any of various plastic packages such as QFP (Quad Flat Package).

The area sealed with the mold resin 14 is the area other than the light transmitting area in the semiconductor package 10. Therefore the surface of the glass 12 is not covered with the mold resin 14, which allows light to pass through the pixel area (light transmitting area) of the image sensor 11.

Next, the lens member 20 is a lens unit which includes a lens 21 and a lens holder (lens holding member) 22 as shown in FIG. 1.

The lens holder 22 is a frame body holding (supporting) the lens 21. The lens 21 is held above the center of the lens holder 22.

The semiconductor package 10 and the lens member 20 are arranged so that the focal point of the image sensor 11 is equal to (matches with) that of the lens 21.

Now the characteristics of the camera module 1 will be explained. The most unique feature about the camera module 1 lies in its structure concerning the attachment of the semiconductor package 10 and the lens member 20.

More specifically, in the semiconductor package 10 a step 18 is formed around the perimeter (outer edge) of the surface of the mold resin 14. As FIG. 3 shows, in the semiconductor package 10 of the present embodiment the step 18 is formed throughout the perimeter of the surface of the mold resin 14. In the present embodiment, the step 18 is a cutout part where the mold resin 14 is removed. As will be described later, the step 18 is formed by cutting a portion of the mold resin 14 molded.

As shown in FIG. 1, the lens holder 22 has a projection 23 formed on its outer ends The projection 23 extends downward (toward the semiconductor package 10). The projection 23 is shaped such that it fits in the step 18. In the present embodiment, as mentioned earlier, the step 18 is formed throughout the perimeter of the mold resin 14. Therefore the projection 23 is formed throughout the perimeter of the lens holder 22 so as to correspond to the step 18. The projection 23 is formed not to exceed the size of the wiring board 13 (board size of FIG. 1). Accordingly, the lens holder 22 remains within the wiring board 13.

As for the camera module 1, the step 18 and the projection 23 allow the semiconductor package 10 and the lens member 20 to be joined to each other. The step 18 and the projection 23 are joined to each other with an adhesive (not shown).

As for the camera module 1, the distance (focal length) between the image sensor 11 and the lens 21 is set to a predetermined value. Therefore the depth (height) of the step 18 is set according to the focal length. The length of the projection 23 is set according to the focal length so that the projection 23 fits in the step 18. In the camera module 1, this enables the semiconductor package 10 and the lens member 20 to be aligned with each other in the direction of an optical axis (lengthwise; up and down).

Further, in the camera module 1, the step 18 and the projection 23 are engaged with each other, so that the semiconductor package 10 and the lens member 20 are joined to each other. In other words, the projection 23 covers the step 18 in the camera module 1. The step 18 and the projection 23 fit together, so that the semiconductor package 10 and the lens member 20 can be aligned with each other in their plane direction (crosswise; from side to side).

In the camera module 1 of the present embodiment, because the step 18 and the projection 23 allow the semiconductor package 10 and the lens member 20 to be aligned with each other in the direction of the optical direction and in the phase direction of the mold resin 14 direction by, it is possible for the semiconductor package 10 and the lens member 20 to be aligned with each other with high precision.

As mentioned above, the semiconductor package 10 and the lens member 20 are integral with each other in the camera module 1 of the present embodiment. The step 18 is formed around the perimeter of the surface of the mold resin 14 which is formed in the semiconductor package 10. The lens member 20 has the projection 23 which fits in the step 18 of the semiconductor package 10. The camera module 1 has the structure in which the lens member 20 is attached to the semiconductor package 10 by virtue of the joint between the step 18 and the projection 23.

This enables the semiconductor package 10 and the lens member 20 to be joined to each other by fitting of the step 18 and the projection 23. With this arrangement, the semiconductor package 10 and the lens member 20 can be aligned with each other not only in the optical axis direction but also in the plane direction. Therefore alignment with higher precision is possible.

The semiconductor package 10, in which components including the wire 15 are packaged, can offer a smaller camera module 1.

Note that the step 18 can be formed to such an extent that the wire 15 is not exposed. Therefore it is possible to cope with any focal length by adjusting the height (depth) of the step 18. For example it is also possible to provide the lens member 20 immediately above the wire 15 through which the image sensor 11 is electrically connected to the wiring board 13. Therefore the camera module 1 can be downsized remarkably.

In the camera module 1 of the present embodiment, it is formed throughout the perimeter (outer edges of four sides) of the mold resin 14. Therefore the semiconductor package 10 and the lens member 20 can be aligned with each other more securely.

Note that the step 18 is not necessarily formed throughout the perimeter of the surface of the mold resin 14, and may be partially formed around the perimeter of the mold resin 14 (that is, the step 18 is formed around at least part of the perimeter of the mold resin 14) if the semiconductor package 10 and the lens member 20 to be attached thereto can be aligned with each other (in the optical axis direction (lengthwise) and crosswise). For example, in the case of a square semiconductor package 10, alignment is possible by forming the step 18 on the opposite two sides of the mold resin 14.

In the camera module 1 of the present embodiment, the step 18 is a cutout part where the mold resin 14 is removed. Therefore the step 18 can be formed easily as will be described later.

In the present embodiment the step 18, the cutout part is concave (concavity) and the projection 23 convex (convexity). However, the step 18 and the projection 23 may be convex and concave, respectively. By allowing the projection 23 to project toward the opposite side of the semiconductor package 10 (oppositely to the projection 23 in FIG. 1), the projection 23 can be concave. Therefore the step 18 and the projection 23 fit in each other as in the case of the present embodiment.

Further, in the camera module 1 of the present embodiment, the step 18 and the projection 23 are joined to each other with an adhesive. Then the step 18 can be formed to such an extent that alignment is possible when the projection 23 is mounted on the step 18. Therefore there is no need for forming the step 18 accurately in order to completely fit (match) with the projection 23.

The camera module 1 of the present embodiment has the structure wherein a semiconductor chip mounted on the semiconductor package 10 is the image sensor 11, and the lens member 20 is mounted on the semiconductor package 10. Then the camera module 1 which is aligned with high precision can be offered.

Such a camera module 1 can be used suitably for various kinds of imaging devices (electronic devices) such as digital still cameras, video cameras, security cameras, mobile phones, on-board cameras, and cameras for intercom.

The image sensor 11 includes circuits for signal processing, and may be the one including other functions or the one not including them. That is to say, in the present embodiment the image sensor 11 is mounted on the wiring board 13. And the parts mounted on the wiring board 13 may be IC or chip parts as well as the image sensor 11. For example, the stack structure can be made on the wiring board 13 by stacking IC chips on top of each other in layers with the image sensor 11. In this case the image sensor 11 is arranged on the top position.

In the present embodiment, as the semiconductor package according to the present invention, the semiconductor package wherein the semiconductor chip is the image sensor 11 has been explained. However, the semiconductor chip mounted on the semiconductor package 10 is applicable to not only a light receiving element but also various kinds of optical elements such as light-emitting elements.

In the present embodiment, as the semiconductor module according to the present invention, the camera module 1 wherein the lens member 20 is mounted on the semiconductor package 10 has been explained. However, the present invention is not limited to this. The semiconductor module according to the present invention may be any module as long as the semiconductor module is constituted by mounting any component on the semiconductor package 10.

In the present embodiment, as FIG. 1 shows, there is a space between the surface of the mold resin 14 and the lens holder 22. However, in a case that there is no irregularities and no parts on an area corresponding to the space, the surface of the mold resin 14 and the lens holder 22 may be in contact with each other without space between them. That is to say, the surface of the mold resin 14 other than the step 18 may be in contact with the lens holder 22. This arrangement, it is possible to realize more stable alignment in the optical axis direction (vertical direction). In addition, the lens member 20 can mitigate the shock on the mold resin 14 (the shock on the semiconductor package 10). In this case, the step 18 is used only for the alignment in the horizontal direction. The focal length can be controlled by the thickness of the lens holder 22.

(2) Method for Manufacturing the Camera Module

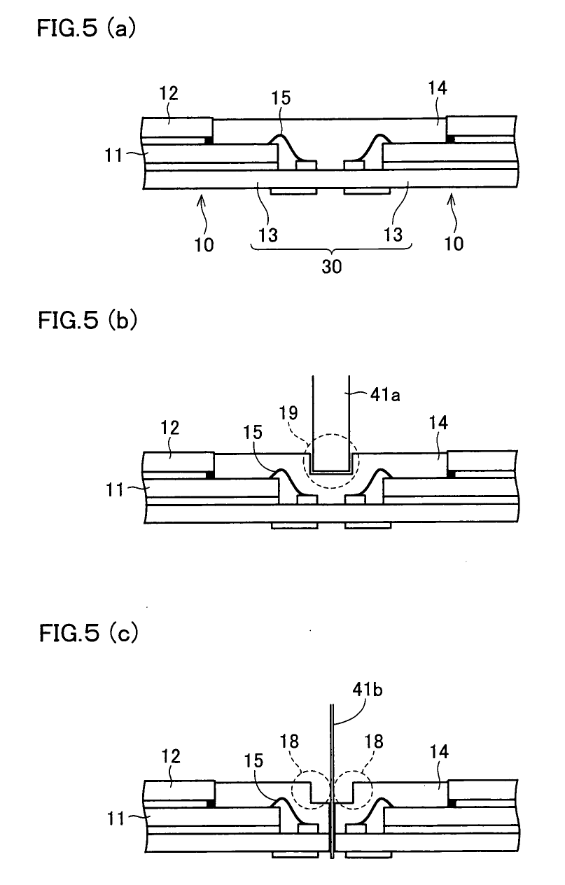

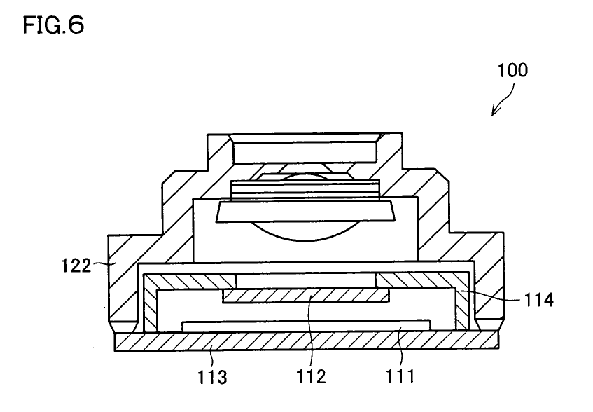

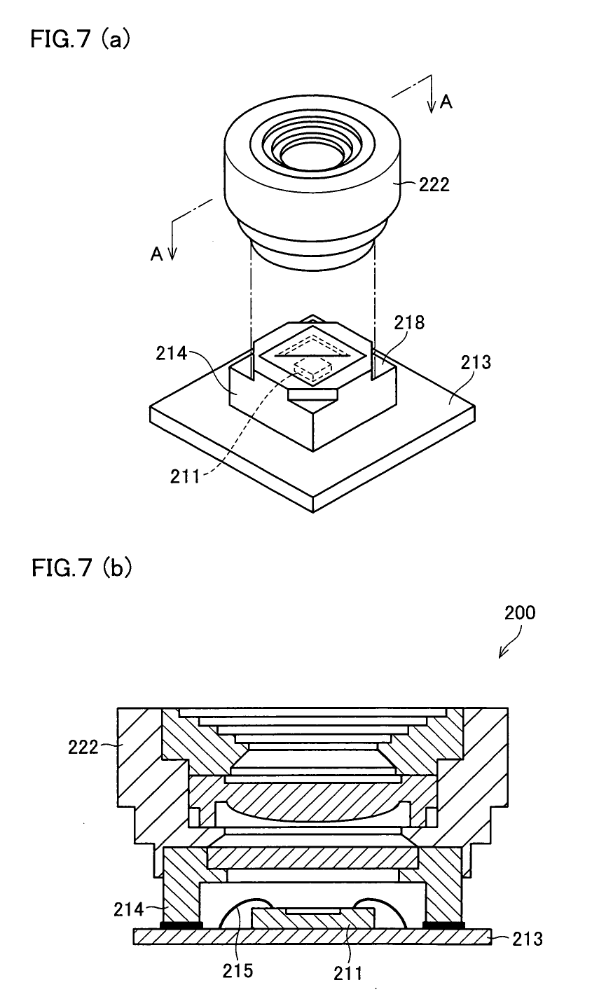

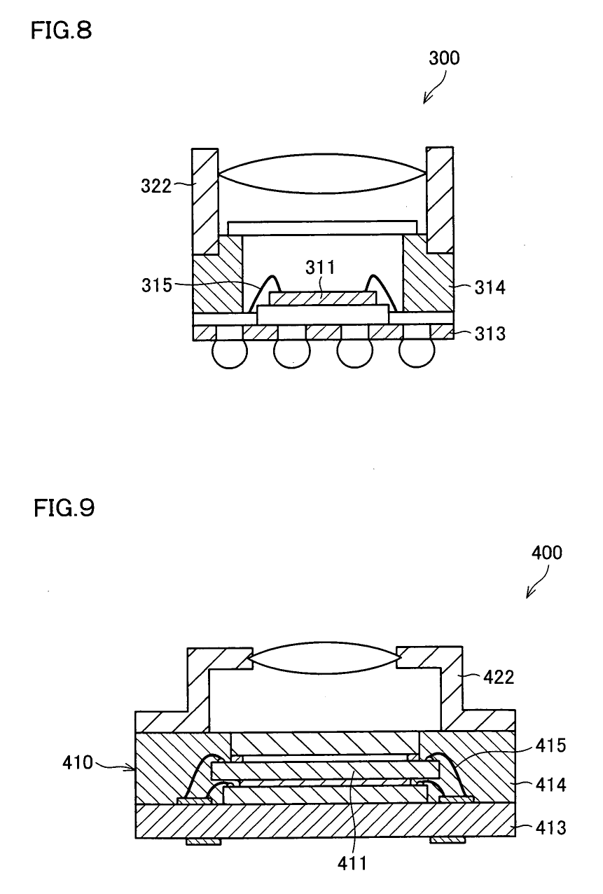

Next, the method for manufacturing the camera module 1 will be explained with reference to the FIG. 4 and FIG. 5(a) through FIG. 5(c). FIG. 4 and FIG. 5(a) through FIG. 5(c) show the process of manufacturing the semiconductor package 10 of the camera module 1.

The method for manufacturing the camera module 1 is characterized by including the step of forming the step 18 in the semiconductor package 10.

In the present embodiment, as FIG. 4 shows, the single board 30 is divided into a plurality of semiconductor packages 10 to produce the semiconductor packages 10. The board 30 is a series of boards in which the wiring boards 13 are arranged in lattice pattern at regular intervals.

Specifically, as FIG. 5(a) shows, the semiconductor package 10 without the step 18 is formed. Each of the semiconductor packages 10 can be produced by mounting the image sensor 11 on each of the wiring substrates 13 contained in the board 30 and electrically connecting the image sensor 11 to the wiring board 13 via the wire 15.

More specifically, the semiconductor package 10 of the FIG. 5(a) is formed, for example, by the steps (A) through (D):

(A) the step of fixing the image sensor 11 onto the wiring board 13 with the die bond material 17;
(B) the step of connecting the pad of the image sensor 11 to the wire bond terminal 13a of the wiring board 13 via the wire 15;
(C) the step of mounting the glass 12 on the pixel area of the image sensor 11; and
(D) the step of sealing the image sensor 11 and the wire with the mold resin 14.

Note that in the step (D), the wiring board 13 on which the image sensor 11 is mounted is subjected to molding in the state of a series of boards (board 30). The molding is done by covering the area other than the area covered with the glass 12 (light transmitting area) with the mold resin 14. The glass 12 is attached to the image sensor 11 with the resin 16. For example, the steps (A) through (D) can be performed with reference to the method described in Patent Document 4 of which Applicant is identical with Applicant of the present application.

Next, the step 18 is formed in the semiconductor package 10 shown in FIG. 5(a) in the manner as FIG. 5(b) and FIG. 5(c) show (step forming step).

In the present embodiment, the step forming step includes first cutting step and second cutting step. In the first cutting step, the step 18 is formed in the adjacent semiconductor package 10 at the same time. Then, in the second cutting step, the adjacent semiconductor package are separated from each other.

More specifically, as FIG. 5(b) shows, the mold resin between the adjacent semiconductor packages 10 of the semiconductor packages 10 formed as shown in FIG. 5(a) and arranged in lattice pattern is cut away with a dicing blade 41a in the first cutting step. In the first cutting step, the mold resin 14 is cut away so that the adjacent semiconductor packages 10 are not separated from each other and the wire 15 is not exposed to the outside. In this manner, a cut part 19 formed with the dicing blade 41a corresponds to the step 18 formed in the adjacent semiconductor packages 10. In the first cutting step, such cutting with the dicing blade 41a is performed with respect to the four sides of the semiconductor package 10.

Next, in the second cutting step, the cut part 19 of FIG. 5 (b) is subjected to dicing again so that the adjacent semiconductor packages 10 are separated from each other. More specifically, as FIG. 5 (c) shows, the cut part 19 formed with the dicing blade 41a in FIG. 5(b) is further cut with a dicing blade 41b. As a result, the adjacent semiconductor packages 10 are separated from each other.

As mentioned above, the step 18 can be formed in the adjacent semiconductor packages 10 at the same time with the dicing blade 41a in the first cutting step. Furthermore, the step 18 can be formed by one dicing with the dicing blade 41a of which thickness is twice greater than the width of the step 18. In addition, by using the board 30 as shown in FIG. 4, the cut part 19 (step 18) can be formed in a plurality of semiconductor packages 10 by one dicing.

Note that the shape and depth of the cut part 19 (step 18) can be changed as needed by adjusting the depth and width of cutting by dicing with the dicing blade 41a.

As described above, the method for manufacturing a camera module according to the present embodiment includes the step forming step of forming the step 18 around the perimeter of the surface of the mold resin 14 of the semiconductor package 10.

With this, it is possible to manufacture the camera module 1 which enables the semiconductor package 10 and the lens member 20 to be easily aligned with each other with high precision.

In the step forming step, a plurality of semiconductor packages 10 are formed from the single board 30. This makes it possible to easily realize the mass production of the semiconductor package 10 and the camera module 1.

The step forming step includes the first cutting step and the second cutting step. In the first cutting step, cutting is performed between the adjacent ones of a plurality of semiconductor packages that the single board 30 forms so that the adjacent semiconductor packages 10 are not separated from each other. In the second cutting step, the cut part formed in the first cutting step is further cut so that the adjacent semiconductor packages 10 are separated from each other.

With this, it is possible to perform the formation of the step 18 and the separation between the individual semiconductor packages 10, by dicing. Therefore the cost for the formation of the step can be reduced. In addition, the formation of the step 18 by cutting makes it possible to achieve greater versatility of step formation and less capital investment in comparison with the formation of the step 18 by using mold.

The edge of the dicing blade 41a used in the first cutting step is thicker than that of the dicing blade 41b used in the second cutting step. With this, the number of cuttings to form the step 18 can be decreased as compared with the case in which the same dicing blade 41b is used in the first and second cutting steps.

In the present embodiment, before a plurality of semiconductor packages 10 are separated from each other, the step 18 is formed by adjusting the depth and width of the cutting. However, the method of forming the step 18 is not limited to this. For example, the cut part 19 (step 18) may be formed by dicing with the dicing blade 41b for a plurality of times in the first cutting step. In alternative example, the step 18 may be formed after the board 30 is divided into the individual semiconductor packages 10. In further alternative example, the step 18 may be formed by molding with the use of a mold by which the step 18 can be formed.

As mentioned above, a semiconductor package according to the present invention is a semiconductor package including: a semiconductor chip mounted on a wiring board; a connecting member through which the wiring board is electrically connected to the semiconductor chip; and a resin sealing member for sealing the semiconductor chip and the connecting member with resin, wherein a step is formed around a perimeter of a surface of the resin sealing member.

According to the above arrangement, the components sealed with resin include the connecting member through which the board is electrically connected to the optical element. In other words, the semiconductor package according to the present invention is the so-called chip-size package. Therefore it is possible to realize the super-small semiconductor package of the same size as the optical element.

Furthermore, according to the above arrangement, the step is formed around the perimeter of the resin sealing member. By attaching the mounting component which fits in this step to the semiconductor package, it is possible to provide a semiconductor package which is suitable for a semiconductor module that allows for highly precise alignment lengthwise and crosswise.

In a semiconductor package according to the present invention, it is preferable that the step is formed throughout the perimeter. With this arrangement, it is possible to more reliably align the semiconductor package with the mounting member to be mounted on the semiconductor package.

In a semiconductor package according to the present invention, it is preferable that the step is a cutout part where resin of the resin sealing member is removed. With this arrangement, the step can be formed by cutting or the like operation. Thus, the step can be formed easily.

In a semiconductor package according to the present invention, the semiconductor chip may be an image sensor. With this arrangement, it is possible to provide a semiconductor package which can be suitably used for a camera module.

In order to solve the above problem, a method for manufacturing a semiconductor package according to the present invention is a method for manufacturing a semiconductor package including: a semiconductor chip mounted on a wiring board; a connecting member through which the wiring board is electrically connected to the semiconductor chip; and a resin sealing member for sealing the semiconductor chip and the connecting member with resin, the method including: the step forming step of forming a step around a perimeter of a surface of the resin sealing member.

According to the above method, the step forming step is included. This makes it possible to manufacture a semiconductor package that is suitable for the semiconductor module as described previously, i.e. the semiconductor module that allows for highly precise alignment lengthwise and crosswise.

A method of manufacturing a semiconductor package according to the present invention is preferably such that in the step forming step, a single board forming the plurality of the semiconductor package is divided into the plurality of the semiconductor package. With this arrangement, the mass production of the semiconductor package can be easily realized.

A method for manufacturing a semiconductor package according to the present invention is preferably such that the step forming step includes: the first cutting step of performing cutting between adjacent ones of the plurality of the semiconductor package so that the adjacent semiconductor packages are not separated from each other; and the second cutting step of cutting a cut part formed in the first cutting step so that the adjacent semiconductor packages are separated from each other.

According to the above method, the cut part formed in the first cutting step is steps of the adjacent semiconductor packages. Thus, it is possible to form the steps in the adjacent semiconductor packages simultaneously by one cutting.

Furthermore, according to the above method, the step forming step can be performed by cutting. Therefore, it is possible to achieve greater versatility of the step forming step and less capital investment in the step forming step.

In a method for manufacturing the semiconductor package according to the present invention, it is preferable that cutting means used in the first cutting step is thicker than that used in the second cutting step. With this arrangement, the number of cuttings to form the step can be decreased as compared with the case in which the same cutting means such as a dicing blade or the like is used in the first and second cutting steps.

A semiconductor module according to the present invention is a semiconductor module in which a mounting component is attached to the semiconductor package according to any one of the semiconductor packages, wherein the mounting component has a fitting member which fits in the step of the semiconductor package, and the step and the fitting member allow the semiconductor package and the mounting component to be joined to each other. With this arrangement, it is possible to provide a downsized semiconductor module that allows for highly precise alignment lengthwise and crosswise.

In the semiconductor module according to the present invention, it is preferable that the step and the fitting member are joined to each other via an adhesive. According to this arrangement, the step and the fitting member are joined to each other with an adhesive. Therefore the step is formed with the degree of accuracy needed to make the step and the fitting member aligned with each other. In other words, it is not necessary to form the step so accurately that the step completely fits (matches) in the fitting member, unlike the case of press-fitting. Therefore the step can be formed easily.

In a semiconductor module according to the present invention, it is preferable that the mounting component is a lens member in which a lens is held by a lens holder. With this arrangement, it is possible to provide a downsized camera module that allows for highly precise alignment lengthwise and crosswise.

An electronic device of the present invention includes one of the foregoing semiconductor modules. With this arrangement, it is possible to provide an electronic device including a semiconductor module that allows for highly precise alignment lengthwise and crosswise.

Also, the present invention can be expressed as follows:

[1] A semiconductor package according to the present invention is a rectangular semiconductor package in which the image sensor 11 having the pixel area to which the glass 12 is attached via the resin 16 is bonded with the die bond material 17 to the wiring board 13 which has the wire bond terminal 13a and the external connection electrode 13b electrically connected to the wire bond terminal 13a, the pad of the image sensor 11 is electrically connected to the wire bond terminal 13a of the wiring board 13 via the wire 15, and the area of the image sensor 11 which is not covered with the glass 12 is sealed with the mold resin 14, wherein the semiconductor package has the step 18 (step structure) that is formed around the outer edges (perimeter) of at least two opposite sides of the mold resin 14 on the side of the semiconductor package where the image sensor 11 is mounted, so that the step 18 is parallel to the external line of the mold resin 14.

[2] The semiconductor package described in [1] may be such that the step 18 around the perimeter is formed by cutting when the outside shape of the package is formed.

[3] A camera module according to the present invention, including an optical component (lens member 20) that includes the lens 21 and the frame member (lens holder 22) having the projection 23 which fits in the step 18 formed around the perimeter and supporting the lens 21, wherein the optical member is attached to the semiconductor package described in [1] so that the projection 23 on the periphery of the optical component fits in the semiconductor package.

The present invention is not limited to the aforementioned embodiments and is susceptible of various changes within the scope of the accompanying claims. Also, an embodiment obtained by suitable combinations of technical means disclosed in the different embodiments are also include within the technical scope of the present invention.

### INDUSTRIAL APPLICABILITY

The present invention, which makes it possible to provide a smaller camera module at low cost, is applied suitable to various kinds of image devices such as digital still cameras, video cameras, security cameras, cameras for mobile phones, on-board cameras, and cameras for intercom.

1: A semiconductor package comprising:
a semiconductor chip mounted on a wiring board;
a connecting member through which the wiring board is electrically connected to the semiconductor chip; and
a resin sealing member for sealing the semiconductor chip and the connecting member with resin, wherein
a step is formed around a perimeter of a surface of the resin sealing member.

2: The semiconductor package according to claim 1 wherein the step is formed throughout the perimeter.

3: The semiconductor package according to claim 1 wherein the step is a cutout part where resin of the resin sealing member is removed.

4: The semiconductor package according to claim 1 wherein the semiconductor chip is an image sensor.

5: The semiconductor package according to claim 4 wherein
the resin sealing member seals with resin an area other than a light transmitting area of the image sensor, and
the light transmitting area is covered with a translucent cover with space therebetween.

6: A method for manufacturing a semiconductor package including:
a semiconductor chip mounted on a wiring board;
a connecting member through which the wiring board is electrically connected to the semiconductor chip; and
a resin sealing member for sealing the semiconductor chip and the connecting member with resin,
the method comprising:
the step forming step of forming a step around a perimeter of a surface of the resin sealing member.

7: The method according to claim 6 wherein,
in the step forming step, a single board forming the plurality of the semiconductor package is divided into the plurality of the semiconductor package.

8: The method according to claim 7, wherein
the step forming step includes: the first cutting step of performing cutting between adjacent ones of the plurality of the semiconductor package so that the adjacent semiconductor packages are not separated from each other; and the second cutting step of cutting a cut part formed in the first cutting step so that the adjacent semiconductor packages are separated from each other.

9: The method according to claim 7 wherein
cutting means used in the first cutting step is thicker than that used in the second cutting step.

10: A semiconductor module in which a mounting component is attached to the semiconductor package according to claim 1, wherein
the mounting component has a fitting member which fits in the step of the semiconductor package, and
the step and the fitting member allow the semiconductor package and the mounting component to be joined to each other.

11: The semiconductor module according to claim 10 wherein the step and the fitting member are joined to each other via an adhesive.

12: The semiconductor module according to claim 11 wherein
the mounting component is a lens member in which a lens is held by a lens holder.

13: The semiconductor module according to claim 10 wherein
the surface of the resin sealing member other than the step is in contact with the mounting component.

14: An electronic device including the semiconductor module according to claim 10.
